(19) United States
(12) Patent Application Publication
(10) Pub. No.: US 2003/0213955 A1
(43) Pub. Date: Nov. 20, 2003

(54) Light emitting apparatus and manufacturing method thereof

(75) Inventors: Yukihiro Noguchi, Motosu-Gun (JP); Hiroshi Tsuchiya, Hirakata-City (JP); Keiichi Sano, Anpachi-gun (JP)

Correspondence Address: MCDERMOTT WILL & EMERY, 600 13TH STREET, N.W., WASHINGTON, DC, 20005-3096, US

(73) Assignee: SANYO ELECTRIC CO., LTD.

(21) Appl. No.: 10/378,673

(22) Filed: Mar. 5, 2003

(30) Foreign Application Priority Data
Mar. 5, 2002 (JP) 2002-059556

(51) Int. Cl. H01L 29/04; H01L 31/036

(52) U.S. Cl. 257/59; 257/72; 438/149; 438/151

(57) ABSTRACT

An organic EL device is fabricated by a novel method to reduce the occurrence of poor luminescence in the organic EL device. The pixel aperture is formed at the part excluding above the contact hole formed for connecting the source electrode of the driving transistor and the pixel electrode of the organic light emitting device. The part where the pixel electrode is uneven is covered with the insulating layer to avoid the short between the pixel electrode and the counter electrode.

### BACKGROUND OF THE INVENTION

1. Field of the Invention

The present invention relates to a light emitting apparatus and a method of manufacturing the light emitting apparatus, and more particularly to a technology for reducing the occurrences of poor luminescence in the light emitting apparatus.

2. Description of the Related Art

Organic electroluminescent displays (hereinafter, also referred to as “organic EL displays” or “organic EL panels”) are attracting attention as new flat-type displays. In particular, active matrix type organic EL displays having thin film transistors (hereinafter, also referred to as “TFTs”) as switching elements are regarded as sweeping out the currently prevailing liquid crystal displays in the near future, and are in a fierce development race for practical application.

Unlike liquid crystal displays, organic EL displays have self-luminous devices. This eliminates the need for a backlight which is indispensable to liquid crystal displays, promising apparatuses of yet lower profile and lighter weight. Moreover, organic EL panels are expected for application as a light emitting devices such as the backlight of liquid crystal displays using a self-luminous characteristic.

It is the fact, however, that many problems to be overcome remain for a practical use. One of such problems is the problem of poor luminescence. When poor luminescence occurs for any reason, non-luminescent area appears on-screen with deterioration in screen visibility, sometimes presenting an obstacle to the display function. It has therefore been a significant challenge to ascertain the cause of the poor luminescence and prevent it effectively so that organic EL displays having fewer non-luminescent areas or no non-luminescent area can be fabricated with high yield.

### SUMMARY OF THE INVENTION

The present invention has been made in view of the foregoing circumstances and an object thereof is to provide a technology for reducing the occurrences of poor luminescence in a light emitting apparatus.

A preferred embodiment according to the present invention relates to a method of manufacturing a light emitting apparatus. This method includes: forming a pixel electrode on a substrate; forming a first insulating layer on the pixel electrode; forming a pixel aperture by removing a part of the first insulating layer and exposing the pixel electrode; and forming a light emitting element layer on the pixel aperture, wherein the pixel aperture is formed at the part of the first insulating layer excluding a part whose shape is changed by being performed a treatment on the pixel electrode or a layer under the pixel electrode.

In the case of an active matrix type organic EL panel, for example, the substrate 10 has the structure in which driving circuits containing switching elements such as TFTs are formed on an insulative substrate, and a planarization film and the like are formed thereon. As employed in this specification, the word “substrate” may mean the substrate itself, or may also mean the substrate including such configuration as the driving circuits. In other words, the target object on which the light emitting apparatus including the pixel electrode, a light emitting element layer, and a counter electrode is formed may be called the substrate on the whole in this specification. The pixel electrode is probably laminated unevenly at the part whose shape is changed under the pixel electrode. If the light emitting element layer is formed on the part, there is a fear that a dark spot arises by poor formation of the light emitting element layer. Moreover, if the counter electrode is formed on the part, there is a fear that both electrodes contact each other and the short circuit arises. The inter-electrode short circuit can be prevented and the occurrences of poor luminescence can be reduced by removing the insulating layer to open the pixel excluding the area whose shape is changed.

The treatment may be an etching. The pixel aperture may be formed at the part of the first insulating layer excluding a part where the pixel electrode is uneven. The pixel aperture may be formed at the part of the first insulating layer excluding an edge part of the pixel electrode. The poor formation of the light emitting element layer can be improved and the inter-electrode short can be avoided by covering the part where the step arises by etching on or under the pixel electrode with the first insulating layer.

The method may further include before forming the pixel electrode: forming a transistor for controlling the light emitting apparatus on the substrate; forming a second insulating layer on the transistor; and forming a contact hole which penetrates to a electrode of the transistor in the second insulating layer; wherein the pixel electrode is formed on an area including the contact hole on the second insulating layer, in forming the pixel electrode; and the pixel aperture is formed at the part of the first insulating layer excluding a part above the contact hole. The surface of the pixel electrode is concave at the part of the contact hole, so that it is favorable that the pixel aperture is provided at the part excluding the contact hole.

Another preferred embodiment according to the present invention relates to a light emitting apparatus. The light emitting apparatus comprises: a substrate; a pixel electrode formed on the substrate; and a light emitting element layer formed on the pixel electrode, wherein the light emitting element layer is formed in the manner that the light emitting element layer does not contact with the pixel electrode at a part whose shape is changed by being performed a treatment on the pixel electrode or a layer under the pixel electrode. The part whose shape is changed may be a part where the pixel electrode is uneven. The part whose shape is changed may be an edge part of the pixel electrode. An insulating layer which covers the part whose shape is changed may be provided between the pixel electrode and the light emitting element layer. The part where the pixel electrode is uneven is covered with the insulating layer, the pixel electrode is thus not connected to the light emitting element layer and the counter electrode formed thereon, so that the poor luminescence and the short can be avoided.

It is to be noted that any arbitrary combination or recombination of the above-described structural components and expressions changed between a method, an apparatus, a system and so forth are all effective as and encompassed by the present embodiments.

Moreover, this summary of the invention does not necessarily describe all necessary features, so that the invention may also be sub-combination of these described features.

### BRIEF DESCRIPTION OF THE DRAWINGS

FIG. 1 shows a circuit structure of a single pixel of a light emitting apparatus according to an embodiment.

FIG. 2 schematically shows the sectional structure of the light emitting apparatus according to the embodiment.

FIG. 3 schematically shows the top view of the light emitting apparatus according to the embodiment.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

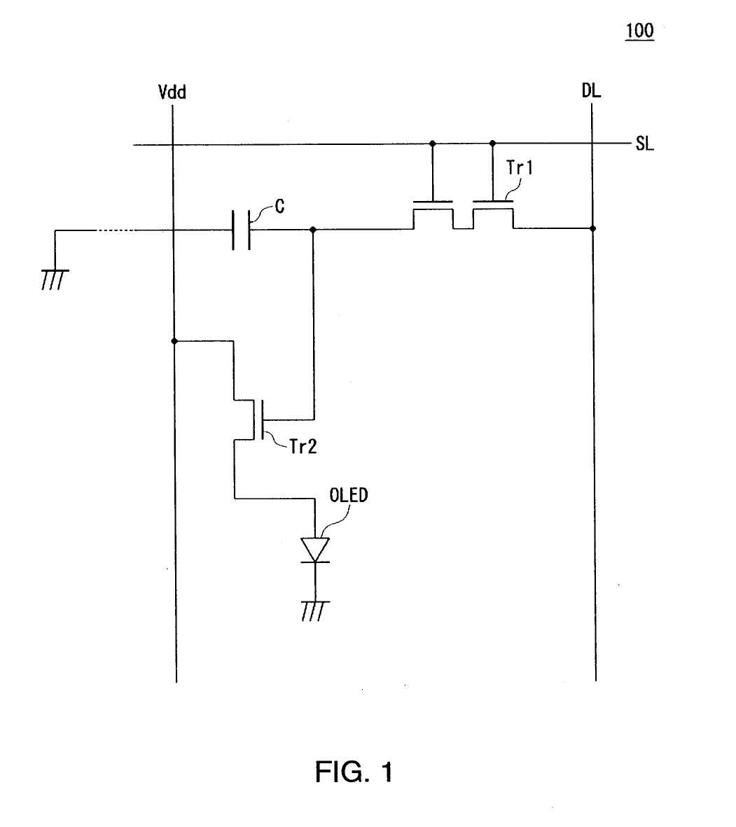

FIG. 1 shows a circuit structure of a single pixel of a light emitting apparatus 100 according to an embodiment. This circuit comprises an organic light emitting element OLED, two transistors Tr1 and Tr2 for controlling the organic light emitting element OLED, a capacitor C, a scanning line SL which transmits scan signals, a data line DL which transmits luminance data, and a power supply line Vdd which supplies electric power.

The power supply line Vdd supplies electric power for making the organic light emitting element OLED emit. The data line DL transmits luminance data to be set to a second transistor Tr2 (hereinafter also referred to as “driving transistor”). The scanning line SL transmits scan signals for activating a first transistor Tr1 (hereinafter also referred to as “switching transistor”), at the timing of making the organic light emitting element OLED emit.

A gate electrode of the switching transistor Tr1 is connected to the scanning line SL. A drain electrode (or a source electrode) of the switching transistor Tr1 is connected to the data line DL. A source electrode (or a drain electrode) of the switching transistor Tr1 is connected to a gate electrode of the driving transistor Tr2. In this embodiment, the switching transistor is a double-gate transistor having two gate electrodes. In another embodiment, the switching transistor may be a single-gate transistor or a multi-gate transistor having three or more gate electrodes. The switching transistor Tr1 may be an n-channel transistor or a p-channel transistor.

A source electrode (or a drain electrode) of the driving transistor Tr2 is connected to an anode of the organic light emitting element OLED. A drain electrode (or a source electrode) of the driving transistor Tr2 is connected to the power supply line Vdd. Similar to the switching transistor Tr1, the driving transistor Tr2 may be a single-gate transistor or a multi-gate transistor, and may be an n-channel transistor or a p-channel transistor.

An anode of the organic light emitting element OLED is connected to the source electrode (or the drain electrode) of the driving transistor Tr2. A cathode of the organic light emitting element OLED is connected to ground potential. An electrode of the capacitor C is connected to the drain electrode (or the source electrode) of the switching transistor Tr1 and the gate electrode of the driving transistor Tr2. Another electrode of the capacitor C is connected to ground potential via a wire not shown in figures, or may be connected to the power supply line Vdd.

An operation of the circuit structured as described above is explained hereinbelow. As the scan signal of the scanning line SL goes high for writing the luminance data to the organic light emitting element OLED, the switching transistor Tr1 turns on, the luminance data which is being inputted to the data line DL is set in the driving transistor Tr2 and the capacitor C. A current which corresponds to the luminance data thus flows between the source electrode and the drain electrode of the driving transistor Tr2, and this current flows in the organic light emitting element OLED, so that the organic light emitting element OLED emits. When the scan signal of the scanning line SL becomes low, the switching transistor Tr1 turns off, but the gate voltage of the driving transistor Tr2 is maintained, so that the organic light emitting element OLED continues emitting according to the set luminance data.

At the next emitting timing, the scan signal of the scanning line SL becomes high again, the switching transistor Tr1 turns on, then the new luminance data which is inputted to the data line DL is set in the driving transistor Tr2 and the capacitor C. Thereby, the organic light emitting element OLED emits corresponding to the new luminance data.

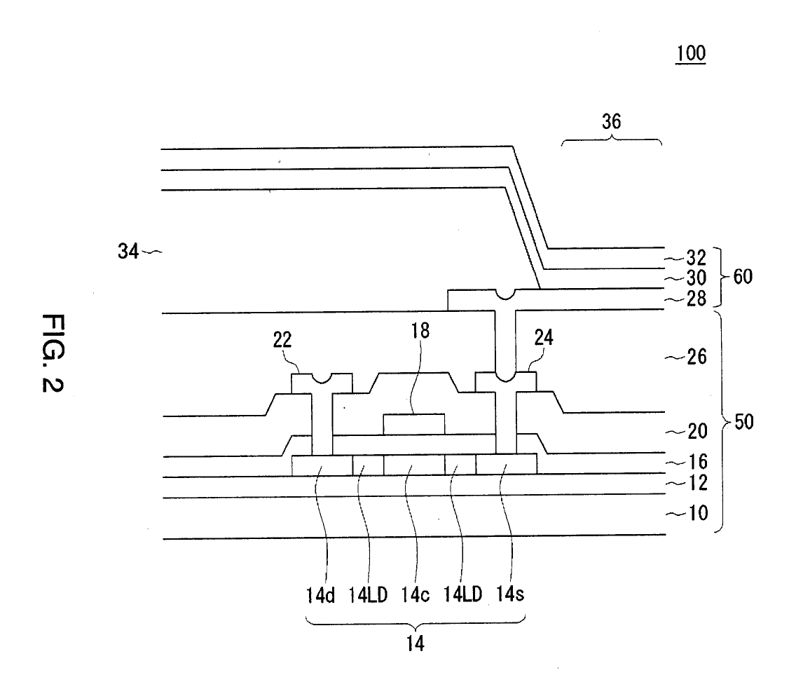

FIG. 2 schematically shows the sectional structure of the light emitting apparatus 100 according to the embodiment. FIG. 2 shows the sectional structure of a part where the driving transistor Tr2 and the organic light emitting element OLED are formed among the circuit of the single pixel shown in FIG. 1. The light emitting apparatus 100 comprises a TFT substrate 50 including an insulating layer 12, an active layer 14, a gate insulating layer 16, a gate electrode 18, an interlayer insulating layer 20, a drain electrode 22, a source electrode 24, and a planarization layer 26 as the example of a second insulating layer, formed on a insulating substrate 10, an organic light emitting device 60 including a pixel electrode 28, a light emitting element layer 30, and a counter electrode 32, and a first insulating layer 34 provided between the TFT substrate 50 and the organic light emitting device 60.

A method of manufacturing this light emitting apparatus 100 is described hereinbelow. The substrate 10 may be a substrate formed by such material as quartz, glass, no-alkali glass, glass ceramic, silicone, metal or plastic. The insulating layer 12 is formed by laminating silicone oxide SiO₂, silicon nitride SiN, silicon oxide nitride SiOₓN_{y}, or like material on the substrate 10, using a plasma CVD or like method. The insulating layer 12 is provided for avoiding the infiltration of impurity ions such as sodium ions from the substrate 10 into the active layer 14, in the case when the substrate 10 is made of glass or like material. The insulating layer 12 may not be provided, in the case when there is not a possibility of the infiltration of impurity ions from the substrate 10.

An amorphous silicon (hereinafter also referred to as “a-Si”) film is formed on the insulating layer 12 using a plasma CVD or like method, and then the a-Si film is annealed by spot irradiation by XeCl excimer laser on the surface thereof, thus melting and recrystallizing the a-Si film into a poly-silicon (hereinafter also referred to as “p-Si”) film. The p-Si film is then etched into an island to form the active layer 14.

The gate insulating layer 16 is formed by laminating silicone oxide SiO₂, silicon nitride SiN or like material on the whole surface of the active layer 14, using a plasma CVD or like method. A film of conductive material which comprises a refractory metal such as chromium (Cr) or molybdenum (Mo) is formed by sputtering on the gate insulating layer 16 and then the gate electrode 18 is formed in a position just above the active layer 14, using photolithography and dry etching technique. At this time, a line for setting a luminance data on the gate electrode 18 is formed simultaneously.

Then N-type or P-type ions are implanted into the active layer 14, which is a p-Si film, through the gate insulating layer 16, using the gate electrode 18 as a mask. N-type or P-type impurity ions are doped into the active layer 14 excluding a part of the active layer 14 not covered with the gate electrode 18. The type of the impurity ion may be selected based on the type of the transistor to be formed. A part of the active layer 14 beneath the gate electrode 18 remains intrinsic or substantially intrinsic p-Si film.

Moreover, a resist whose width is narrower than the width of the active layer 14, for covering the gate electrode 18 and the gate insulating layer 16, is formed. The ions are then implanted using the resist as a mask. The part of the active layer 14 not covered with the resist is highly doped with the impurity ions, to be a source area 14a and a drain area 14d. The part of the active layer 14 covered with the resist is low doped with the impurity ions, to be an LDD area. The source area 14s, a channel 14c, the drain area 14d, and the LDD area 14LD are thus formed by ion doping.

After removing the resist, the interlayer insulating layer 20 is formed by laminating silicone oxide SiO₂, silicon nitride SiN or like material on the whole surface, using a plasma CVD. Then contact holes penetrating the interlayer insulating layer 20 and reaching the active layer 14 are formed in positions corresponding to the source area 14s and the drain area 14d, and the source electrode 26 and the drain electrode 28 are formed by filling these contact holes with a metal such as aluminum (Al). Thereafter, the planarization layer 26 is formed thereon by depositing an organic resin or like material. This planarization layer 26 planarizes the surface of the substrate by covering the part where the circuit such as the transistor is formed. This planarization of the surface of the TFT substrate 50, before forming the organic light emitting device 60, is very important for preventing poor luminescence of the organic light emitting device 60, as described hereinbelow.

A contact hole penetrating the planarization layer 26 and reaching the source electrode 24 is formed in a position corresponding to the source electrode 24, and the pixel electrode 28 is formed by depositing a transparent electrode material such as indium tin oxide (ITO) thereon, and patterning the deposited material. The pixel electrode is an anode in this embodiment. The anode is made of such material as indium tin oxide (ITO), tin oxide (SnO₂), or indium oxide (In₂O₃). ITO is typically used because of its hole injection efficiency and low surface resistance. When the ITO is deposited, a part where the contact hole is formed by performing the etching treatment to the planarization layer 26 beneath the pixel electrode 28 becomes deep concavity, so that the pixel electrode 28, which is formed thereon, has a concavity lower than surroundings at the position on the contact hole. Namely, the surface of the pixel electrode 28 is uneven, and has a level difference just above the contact hole. The pixel electrode 28 also has a level difference at the edge part etched in patterning.

The first insulating layer 34 is formed on the whole surface of the pixel electrode 28, then the pixel aperture 36 is formed by removing a part of the first insulating layer 34 by etching and exposing the pixel electrode 28. The pixel aperture 36 is formed at the part of the first insulating layer 34 excluding a part whose shape is changed by being performed a treatment on the pixel electrode or a layer under the pixel electrode, such as a part of the contact hole formed at the planarization layer 26 beneath the pixel electrode 28, and an edge part with a level difference of the pixel electrode 28. The part of the contact hole and the edge remain covered with the first insulating layer 34, and do not contact with the light emitting element layer 30 provided thereon.

A light emitting element layer 30 is formed on the pixel electrode 28. The light emitting element layer 30 includes organic layers such as an anode buffer layer, a hole transporting layer, a light emitting layer, and an electron transporting layer. In general, these organic layers are formed by vacuum evaporation in a multi-chamber type fabrication system having a plurality of formation chambers. The anode buffer layer, the hole transporting layer, and the electron transporting layer may be provided if necessary.

The hole transporting layer is made of such material as N,N′-di(naphthalene-1-yl)-N,N′-diphenyl-benzidine, 4,4′,4″-tris(3-methylphenylphenylamino)triphenylamine (MTDATA), or N,N′-diphenyl-N,N′-di(3-methylphenyl)-1,1′-biphenyl-4,4′-diamine. The luminescent layer is made of such material as aluminum-quinoline complex (Alq3) or bis(10-hydroxybenzo[h]quinolinato) beryllium (Bebq2) containing a quinarcridon derivative. The electron transporting layer is made of such material as Alq3 or Bebq2. The anode buffer layer is made of such material as copper phthalocyanine, m-MTDATA, or aluminum oxide.

A counter electrode 32 is formed on the light emitting element layer 30. The counter electrode is a cathode in this embodiment. The cathode is made of such material as an aluminum alloy containing a trace quantity of lithium, a magnesium indium alloy, or a magnesium silver alloy. The counter electrode 32 may have a double-layer structure having a lithium fluoride (LiF) layer and an aluminum (Al) layer in this order from the electron transporting layer.

When the light emitting element layer 30 is evaporated on the pixel electrode 28, if the pixel electrode 28 is uneven, an organic light emitting material is not evaporated well on the uneven part, so that there is a fear that the uneven part becomes a non-emitting area (dark spot). Moreover, if a gap arises at the step caused by poor evaporation of the organic material, the cathode electrode material penetrates the gap, so that there is a fear that the electrical short arises. In the case of the inter-electrode short, a current flows in the short circuit intensively when applied a voltage, so that the whole pixel does not emit and becomes a dark spot, because a current does not flow in the light emitting element layer 30.

In this embodiment, the part whose shape is changed by being performed a treatment on the pixel electrode 28 or a layer under the pixel electrode 28 is covered with the first insulating layer 34, and the pixel aperture 36 is not provided thereon, so that the poor formation of the light emitting layer 30 and the poor luminescence caused by the inter-electrode short are prevented.

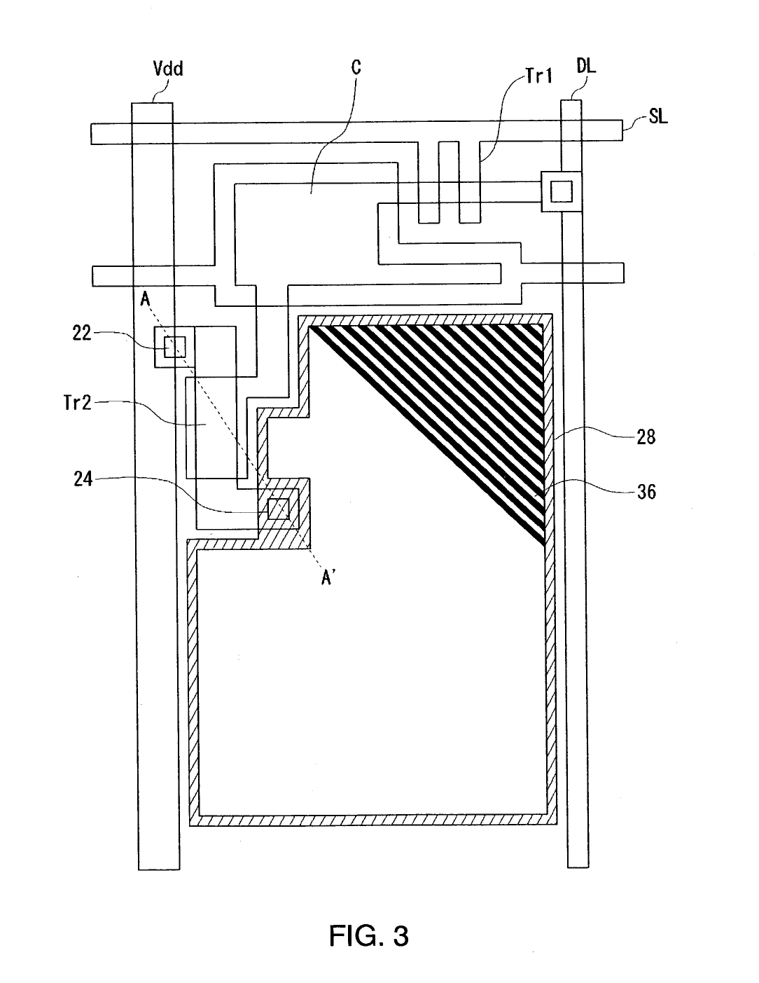

FIG. 3 schematically shows a top view of the light emitting apparatus 100 according to the embodiment. FIG. 3 shows the top view of the circuit of a single pixel as shown in FIG. 1. The pixel electrode 28 is hatched with oblique lines upper left to lower right, and the pixel aperture 36 is hatched partially with oblique lines lower left to upper right. The sectional view shown in FIG. 2 is taken on line A-A′ in FIG. 3. The part where a contact hole is formed on the source electrode 24 of the driving transistor Tr2 is not opened as a pixel, because the first insulating layer 34 is formed between the pixel electrode 28 and the light emitting element layer 30. The pixel is opened at only the even part of the pixel electrode 28, so that the occurrence of poor luminescence can be prevented.

The present invention has been described based on embodiments which are only exemplary. It will be understood by those skilled in the art that there exist other various modifications to the combination of each component and process described above and that such modifications are encompassed by the scope of the present invention. Such modifications will be described hereinbelow.

In the foregoing embodiment, the driving transistor Tr2 is a top-gate type transistor in which the gate electrode 18 exists above the active layer 14. Nevertheless, the driving transistor Tr2 may be a bottom-gate type transistor in which the gate electrode 18 exists below the active layer 14.

In the foregoing embodiment, the example of the organic light emitting device is explained, nevertheless the light emitting device may be an inorganic light emitting device. In the foregoing embodiment, the electrode of the driving transistor Tr2 is connected to the anode of the organic light emitting device, nevertheless the electrode of the driving transistor Tr2 may be connected to the cathode of the organic light emitting device.

Although the present invention has been described by way of exemplary embodiments, it should be understood that many changes and substitutions may further be made by those skilled in the art without departing from the scope of the present invention which is defined by the appended claims.

What is claimed is:

1. A method of manufacturing a light emitting apparatus, including:
forming a pixel electrode on a substrate;
forming a first insulating layer on the pixel electrode;
forming a pixel aperture by removing a part of the first insulating layer and exposing the pixel electrode; and
forming a light emitting element layer on the pixel aperture,
wherein the pixel aperture is formed at the part of the first insulating layer excluding a part whose shape is changed by being performed a treatment on the pixel electrode or a layer under the pixel electrode.

2. A method according to claim 1, wherein the treatment is an etching.

3. A method according to claim 1, wherein the pixel aperture is formed at the part of the first insulating layer excluding a part where the pixel electrode is uneven.

4. A method according to claim 2, wherein the pixel aperture is formed at the part of the first insulating layer excluding a part where the pixel electrode is uneven.

5. A method according to claim 1, wherein the pixel aperture is formed at the part of the first insulating layer excluding an edge part of the pixel electrode.

6. A method according to claim 2, wherein the pixel aperture is formed at the part of the first insulating layer excluding an edge part of the pixel electrode.

7. A method according to claim 1, further including before said forming the pixel electrode:
forming a transistor for controlling the light emitting apparatus on the substrate;
forming a second insulating layer on the transistor; and
forming a contact hole which penetrates to a electrode of the transistor in the second insulating layer;
wherein the pixel electrode is formed on an area including the contact hole on the second insulating layer, in said forming the pixel electrode; and
the pixel aperture is formed at the part of the first insulating layer excluding a part above the contact hole.

8. A method according to claim 2, further including before said forming the pixel electrode:
forming a transistor for controlling the light emitting apparatus on the substrate;
forming a second insulating layer on the transistor; and
forming a contact hole which penetrates to a electrode of the transistor in the second insulating layer;
wherein the pixel electrode is formed on an area including the contact hole on the second insulating layer, in said forming the pixel electrode; and
the pixel aperture is formed at the part of the first insulating layer excluding a part above the contact hole.

9. A method according to claim 3, further including before said forming the pixel electrode:
forming a transistor for controlling the light emitting apparatus on the substrate;
forming a second insulating layer on the transistor; and
forming a contact hole which penetrates to a electrode of the transistor in the second insulating layer;
wherein the pixel electrode is formed on an area including the contact hole on the second insulating layer, in said forming the pixel electrode; and
the pixel aperture is formed at the part of the first insulating layer excluding a part above the contact hole.

10. A method according to claim 4, further including before said forming the pixel electrode:
forming a transistor for controlling the light emitting apparatus on the substrate;
forming a second insulating layer on the transistor; and
forming a contact hole which penetrates to a electrode of the transistor in the second insulating layer;
wherein the pixel electrode is formed on an area including the contact hole on the second insulating layer, in said forming the pixel electrode; and
the pixel aperture is formed at the part of the first insulating layer excluding a part above the contact hole.

11. A method according to claim 5, further including before said forming the pixel electrode:
forming a transistor for controlling the light emitting apparatus on the substrate;
forming a second insulating layer on the transistor; and
forming a contact hole which penetrates to a electrode of the transistor in the second insulating layer;
wherein the pixel electrode is formed on an area including the contact hole on the second insulating layer, in said forming the pixel electrode; and
the pixel aperture is formed at the part of the first insulating layer excluding a part above the contact hole.

12. A method according to claim 6, further including before said forming the pixel electrode:
forming a transistor for controlling the light emitting apparatus on the substrate;
forming a second insulating layer on the transistor; and
forming a contact hole which penetrates to a electrode of the transistor in the second insulating layer;
wherein the pixel electrode is formed on an area including the contact hole on the second insulating layer, in said forming the pixel electrode; and
the pixel aperture is formed at the part of the first insulating layer excluding a part above the contact hole.

13. A light emitting apparatus, comprising:
a substrate;
a pixel electrode formed on said substrate; and
a light emitting element layer formed on said pixel electrode,
wherein said light emitting element layer is formed in the manner that said light emitting element layer does not contact with said pixel electrode at a part whose shape is changed by being performed a treatment on said pixel electrode or a layer under said pixel electrode.

14. A light emitting apparatus according to claim 13, wherein the part whose shape is changed is a part where the pixel electrode is uneven.

15. A light emitting apparatus according to claim 13, wherein the part whose shape is changed is an edge part of the pixel electrode.

16. A light emitting apparatus according to claim 13, wherein an insulating layer which covers the part whose shape is changed is provided between said pixel electrode and said light emitting element layer.

17. A light emitting apparatus according to claim 14, wherein an insulating layer which covers the part whose shape is changed is provided between said pixel electrode and said light emitting element layer.

18. A light emitting apparatus according to claim 15, wherein an insulating layer which covers the part whose shape is changed is provided between said pixel electrode and said light emitting element layer.
